(19) United States
(12) Patent Application Publication
(10) Pub. No.: US 2022/0010983 A1
(43) Pub. Date: Jan. 13, 2022

(54) HUMIDITY CONTROL DEVICE, METHOD OF ABSORBING AND DRAINING MOISTURE, METHOD OF GENERATING POWER, HEAT EXCHANGE VENTILATION SYSTEM, AND METHOD OF CONTROLLING HEAT EXCHANGE VENTILATION SYSTEM

(71) Applicant: Panasonic Intellectual Property Management Co., Ltd., Osaka (JP)

(72) Inventors: HYUNJEONG NAM, Nara (JP); HIROMASA TAMAKI, Osaka (JP); YURIKO KANEKO, Nara (JP); HIROKI SATO, Shiga (JP); TAKASHI IKAWA, Fukuoka (JP)

(21) Appl. No.: 17/483,653

(22) Filed: Sep. 23, 2021

Related U.S. Application Data
(63) Continuation of application No. PCT/JP2020/021675, filed on Jun. 2, 2020.

(30) Foreign Application Priority Data
Jun. 24, 2019 (JP) 2019-116716
Mar. 23, 2020 (JP) 2020-051760

(51) Int. Cl. F24F 3/14; F24F 13/22

(52) U.S. Cl. CPC F24F 3/14; F24F 2003/1446; F24F 13/222

(57) ABSTRACT

A humidity control device includes a condenser and a water absorber-drainer. The condenser has a first region and a second region. The first region is a region having hydrophilicity and where moisture is condensed. The condensed moisture is moved by gravity to the water absorber-drainer via the second region. The water absorber-drainer includes a temperature control member and has a water absorption surface and a water drainage surface. When a temperature of the water absorber-drainer is in a first temperature region, the water absorber-drainer absorbs through the water absorption surface the moisture moved from the condenser. When the temperature of the water absorber-drainer is controlled to be in a second temperature region by an operation of the temperature control member, the water absorber-drainer drains the absorbed moisture through the water drainage surface.

### BACKGROUND

### 1. Technical Field

The present disclosure relates to a humidity control device, a method of absorbing and draining moisture with use of the humidity control device, and a method of generating power. The present disclosure also relates to a heat exchange ventilation system that includes the aforementioned humidity control device, and a method of controlling the heat exchange ventilation system.

### 2. Description of the Related Art

A heat exchange ventilation system that includes a total heat exchanger is known. This system enables, for example, an exchange of temperature and humidity between air that is taken in from the outside of a room and air that is drained from the inside of the room.

Japanese Unexamined Patent Application Publication No. 2009-281707 discloses a heat recovery device that includes a total heat exchanger. The device further includes a cooler. In the device, relative humidity of drained air that flows into the total heat exchanger is increased by the cooler so that efficiency in a heat exchange can be improved.

Japanese Unexamined Patent Application Publication No. 2007-132614 discloses an absorption heat exchanger module. The module uses an organic polymer-based absorbent to control humidity. Heat is exchanged through absorption and desorption of water vapor with respect to the absorbent.

### SUMMARY

One non-limiting and exemplary embodiment provides a novel humidity control device capable of catching, absorbing, and draining moisture in an atmosphere, and a heat exchange ventilation system including the humidity control device.

The present disclosure provides the following device.

In one general aspect, the techniques disclosed here feature a humidity control device including a condenser and a water absorber-drainer. The condenser has a first region and a second region. The first region is a region having hydrophilicity and where moisture is condensed. The condensed moisture is moved by gravity to the water absorber-drainer via the second region. The water absorber-drainer includes a temperature control member and has a water absorption surface and a water drainage surface. When a temperature of the water absorber-drainer is in a first temperature region, the water absorber-drainer absorbs through the water absorption surface the moisture moved from the condenser. When the temperature of the water absorber-drainer is controlled to be in the second temperature region by an operation of the temperature control member, the water absorber-drainer drains the absorbed moisture through the water drainage surface.

According to the present disclosure, it is possible to achieve, for example, a novel humidity control device capable of catching, absorbing, and draining moisture in an atmosphere, and a heat exchange ventilation system that includes the humidity control device. Further advantages and effects in one aspect of the present disclosure will become apparent from the specification and the drawings. Such advantages and/or effects will be each provided by the features described in some embodiments, the specification, and the drawings. However, not all of those are necessarily required to be provided to obtain one or more identical features.

Additional benefits and advantages of the disclosed embodiments will become apparent from the specification and drawings. The benefits and/or advantages may be individually obtained by the various embodiments and features of the specification and drawings, which need not all be provided in order to obtain one or more of such benefits and/or advantages,

### BRIEF DESCRIPTION OF THE DRAWINGS

FIG. 1A is a plan view schematically illustrating a humidity control device according to Embodiment 1;

FIG. 1B is a sectional view schematically illustrating the section IB-IB of the humidity control device in FIG. 1A;

FIG. 2 is a plan view schematically illustrating an example of a condenser included in the humidity control device according to Embodiment 1;

FIG. 3A is a schematic view illustrating an example of condensation of water at the condenser and absorption of water at a water absorber-drainer in the humidity control device according to Embodiment 1;

FIG. 3B is a schematic view illustrating an example of condensation of water at the condenser and absorption of water at the water absorber-drainer in the humidity control device according to Embodiment 1;

FIG. 3C is a schematic view illustrating an example of condensation of water at the condenser and absorption of water at the water absorber-drainer in the humidity control device according to Embodiment 1;

FIG. 3D is a schematic view illustrating an example of condensation of water at the condenser and absorption of water at the water absorber-drainer in the humidity control device according to Embodiment 1;

FIG. 4A is a plan view schematically illustrating another example of the condenser included in the humidity control device according to Embodiment 1;

FIG. 4B is a sectional view schematically illustrating the section IVB-IVB of the condenser in FIG. 4A;

FIG. 5 is a sectional view schematically illustrating an example of the water absorber-drainer that can be included in the humidity control device according to Embodiment 1, and a partially enlarged view thereof;

FIG. 6 is a sectional view schematically illustrating a modification of the humidity control device according to Embodiment 1;

FIG. 7A is a schematic view illustrating an example of a form of absorption and drainage of water in a humidity control device including a temperature control member that is a thermoelectric conversion module;

FIG. 7B is a schematic view illustrating an example of a form of absorption and drainage of water in a humidity control device including a temperature control member that is a thermoelectric conversion module;

FIG. 8 is a sectional view schematically illustrating a humidity control device according to Embodiment 2;

FIG. 9 is a sectional view schematically illustrating an example of a joint portion between a water absorber-drainer and a reinforcer in the humidity control device according to Embodiment 2;

FIG. 10 is a sectional view schematically illustrating another example of the joint portion between the water absorber-drainer and the reinforcer in the humidity control device according to Embodiment 2;

FIG. 11 is a schematic view illustrating an example of a heat exchange ventilation system according to the present disclosure;

FIG. 12 is a perspective view schematically illustrating an example of a total heat exchanger that can be included in the heat exchange ventilation system according to the present disclosure;

FIG. 13 is a perspective view schematically illustrating another example of the total heat exchanger that can be included in the heat exchange ventilation system according to the present disclosure;

FIG. 14 is a flowchart illustrating an example of a method of controlling the heat exchange ventilation system according to the present disclosure; and

FIG. 15 is a flowchart illustrating another example of the method of controlling the heat exchange ventilation system according to the present disclosure.

### DETAILED DESCRIPTION

### Embodiments of Present Disclosure

Hereinafter, embodiments of the present disclosure will be described with reference to the drawings. A humidity control device, a heat exchange ventilation system, and methods according to the present disclosure are, however, not limited to the specific embodiments presented below.

### Device

### Embodiment 1

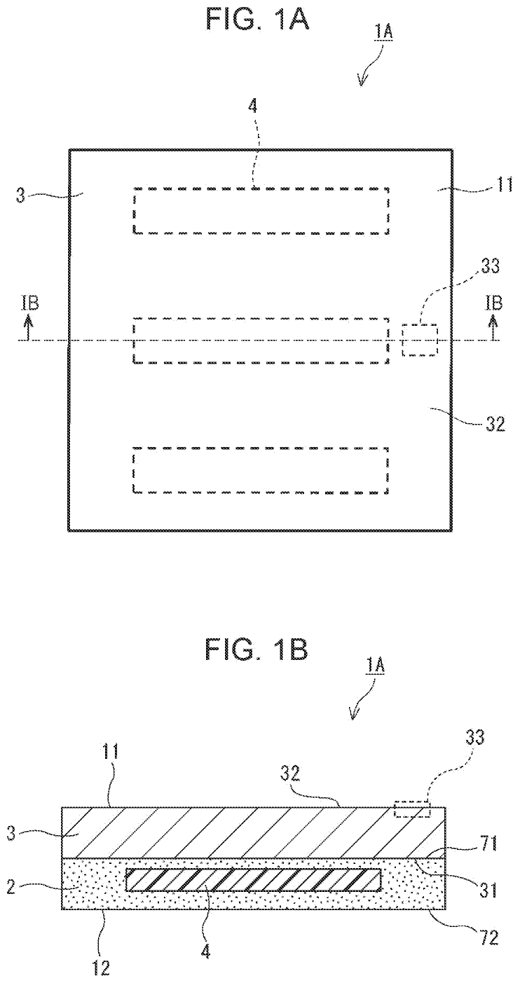

A humidity control device according to Embodiment 1 is illustrated in FIG. 1A and FIG. 1B. FIG. 1B illustrates the section IB-IB of a humidity control device 1A in FIG. 1A. The humidity control device 1A includes a water absorber-drainer 2, a condenser 3, and a temperature control member 4. The humidity control device 1A has a stack structure that includes the water absorber-drainer 2 and the condenser 3. The condenser 3 and the water absorber-drainer 2 are in contact with each other. The temperature control member 4 is provided in the inside of the water absorber-drainer 2. One main surface 11 of the humidity control device 1A is constituted by the condenser 3. The condenser 3 is exposed at the main surface 11. Another main surface 12 of the humidity control device 1A is constituted by the water absorber-drainer 2. The water absorber-drainer 2 is exposed at the main surface 12. The water absorber-drainer 2 and the condenser 3 of the humidity control device 1A each have a layer shape.

At the condenser 3, condensation of moisture in an atmosphere is possible. The condenser 3 can supply condensed moisture to the water absorber-drainer 2. The moisture in an atmosphere is typically moisture in air. The water absorber-drainer 2 includes the temperature control member 4 and has a water absorption surface 71 and a water drainage surface 72. The condenser 3 and the water absorption surface 71 of the water absorber-drainer 2 are in contact with each other. The temperature control member 4 can control the temperature of the water absorber-drainer 2 to be in a first temperature region and/or a second temperature region by being operated and/or stopped. The water absorber-drainer 2 absorbs moisture in the first temperature region and drains absorbed moisture in the second temperature region, which is present on the high temperature side compared with the first temperature region. The state in which the second temperature region is present on the high temperature side compared with the first temperature region means t1H<t2L, Here, t1L represents the lower limit temperature of the first temperature region, t1H (>t1L) represents the upper limit temperature of the first temperature region, t2L represents the lower limit temperature of the second temperature region, and t2H (>t2L) represents the upper limit temperature of the second temperature region.

The water absorber-drainer 2 can absorb moisture through the water absorption surface 71. The water absorber-drainer 2 can drain moisture through the water drainage surface 72. The moisture drained from the water absorber-drainer 2 can move to the outside of the humidity control device 1A through the main surface 12.

In the humidity control device 1A, moisture in an atmosphere can be caught by the condenser 3. The caught moisture can be absorbed by the water absorber-drainer 2 in the first temperature region. Absorbed moisture can be drained when the temperature of the water absorber-drainer 2 enters the second temperature region. It is thus possible in the humidity control device 1A to catch, absorb, and drain moisture in an atmosphere, Drainage may be drainage to a member in contact with the humidity control device 1A, for example, the main surface 12 thereof. In addition, drainage may be drainage as water vapor and may be drained as liquid.

The condenser 3 has, for example, the following configuration.

The condenser 3 has a first main surface 31 and a second main surface 32 facing the first main surface 31 (refer to FIG. 1A and FIG. 1B). A distance between the water absorber-drainer 2 and the first main surface 31 is smaller than a distance between the water absorber-drainer 2 and the second main surface 32. The second main surface 32 is an exposed surface. The condenser 3 further has a first region in contact with the second main surface 32. The first region has hydrophilicity. The moisture in an atmosphere is condensed in the first region. The moisture in an atmosphere may be further condensed in a region other than the first region at the second main surface 32. The moisture that has been condensed in the first region permeates the condenser 3 from the second main surface 32 to the first main surface 31. For permeation of moisture, the condenser 3 may have, for example, a through hole through which condensed moisture can pass. The through hole connects the first main surface 31 and the second main surface 32 to each other. A direction in which the through hole extends may be a thickness direction of the condenser 3. The condenser 3 may be a porous layer having a pore that connects the first main surface 31 and the second main surface 32 to each other. The condenser 3 may be a layer that has a mesh structure. Examples of the material that constitutes the condenser 3 are metals, resins, and composite materials of metals and resins. By using the humidity control device 1A in a state in which the condenser 3 is on or above the water absorber-drainer 2, it is possible to use gravity for permeation of moisture in the condenser 3.

The condenser 3 usually has a second region that differs from the first region. Typically, the first region and the second region differ from each other in the degree of hydrophilicity. The second region may have hydrophobicity. Hydrophilicity and hydrophobicity can be determined by, for example, the contact angle of water, When the condenser 3 has the first region and the second region, the moisture that has been condensed in the first region can permeate the condenser 3 through the second region. In other words, the second region includes a path in which the moisture that has been condensed in the first region is moved to the water absorber-drainer 2 by, for example. gravity. Hereinafter, such a form in which the condenser 3 has the first region and the second region will be described as “form A”. In the form A, it is possible to improve efficiency in catching moisture at the condenser 3 and supplying moisture from the condenser 3 to the water absorber-drainer 2.

The form of the condenser 3 having the first region and the second region is not limited to the aforementioned example. The aforementioned example has a surface having the first region and the second region.

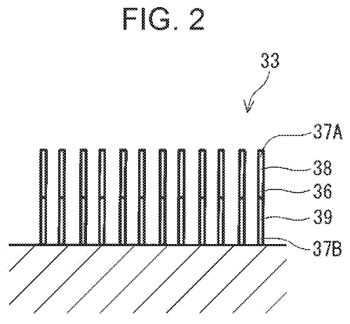

An example of the form A is illustrated in FIG. 2. The condenser 3 in the example includes columnar bodies 36 extending in a direction away from the water absorption surface 71 of the water absorber-drainer 2. Each of the columnar bodies 36 in FIG. 2 extends in a direction perpendicular to a surface of the condenser 3 and includes a first end 37A and a second end 37B. The first end 37A has an outer peripheral surface 38 corresponding to the first region, and the second end 37B has an outer peripheral surface 39 corresponding to the second region. The number of each of the outer peripheral surface 38 and the outer peripheral surface 39 of each columnar body 36 in FIG. 2 is one. Each columnar body 36 may have outer peripheral surfaces 38 and/or outer peripheral surfaces 39. The boundary between the first region and the second region in each columnar body 36 in FIG. 2 is present in the vicinity of the center of the columnar body 36 in the length direction. The boundary may be present at a freely selected portion in the columnar body 36. The shape of each columnar body 36 in FIG. 2 may be columnar, such as a cylinder or prism shape.

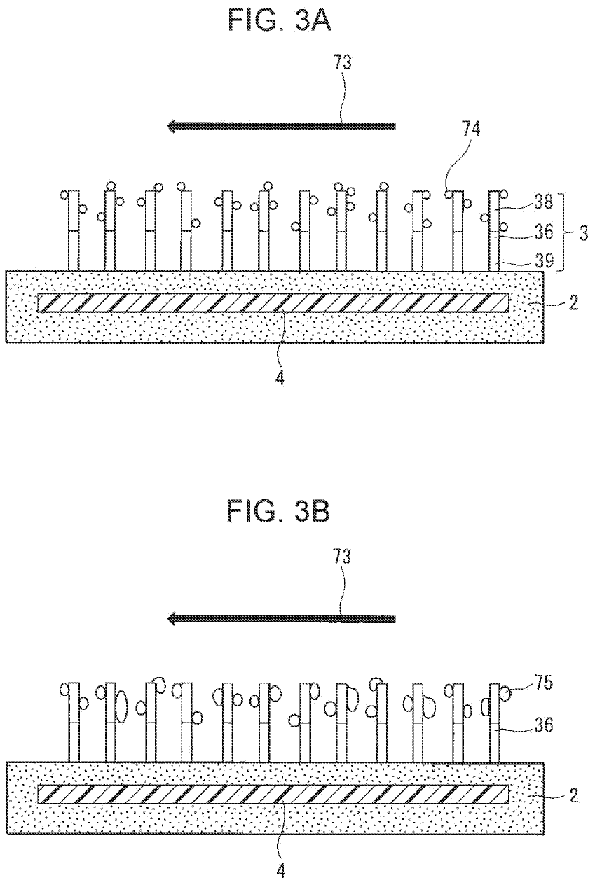

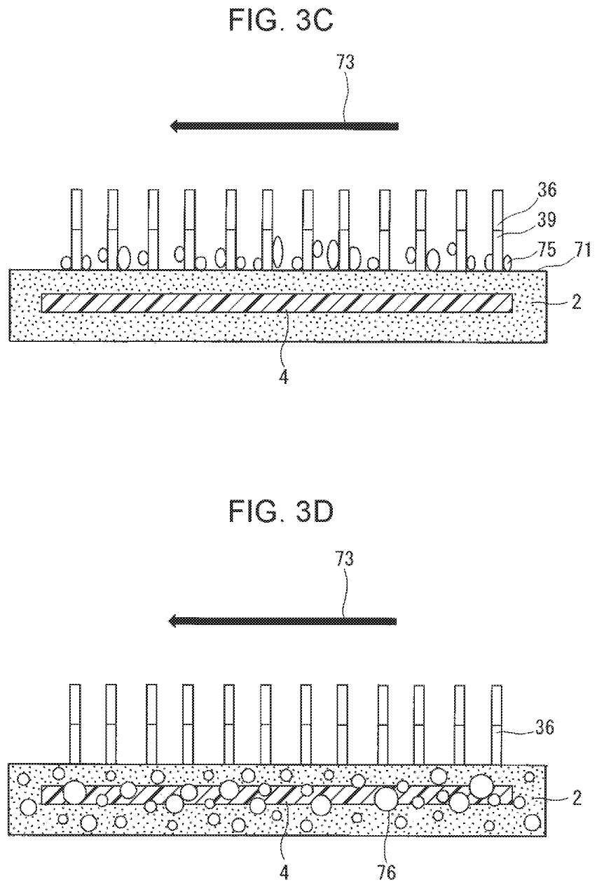

The condenser 3 may be constituted by the columnar bodies 36. In this case, the columnar bodies 36 extend, for example, from the water absorption surface 71 of the water absorber-drainer 2. Examples of condensation of water at the condenser 3 and absorption of water at the water absorber-drainer 2 are illustrated in FIG. 3A to FIG. 3D.

First, as illustrated in FIG. 3A, moisture contained in an atmosphere 73 is condensed on the outer peripheral surface 38 of the condenser 3 and generates water droplets 74. Next, as illustrated in FIG. 3B, the generated water droplets 74 aggregate and become water droplets 75 each having a larger size. Next, as illustrated in FIG. 3C, the water droplets 75 fall onto the water absorption surface 71 of the water absorber-drainer 2 due to their own weight. In this case, when the outer peripheral surface 39 corresponding to the second region has hydrophobicity, efficiency in the movement of moisture from the condenser 3 to the water absorber-drainer 2 is improved. Next, as illustrated in FIG. 3D, moisture 76 that has reached the water absorption surface 71 is absorbed by the water absorber-drainer 2 present in the first temperature region.

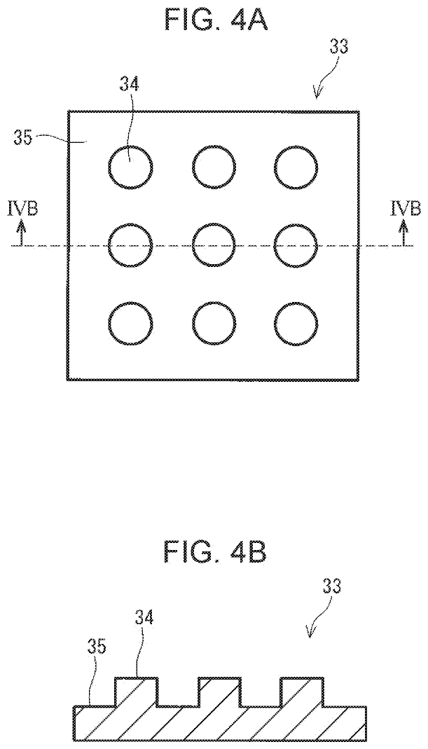

An example of the form A is illustrated in FIG. 4A and FIG. 4B. FIG. 4A and FIG. 4B each illustrate a part 33 illustrated in FIG. 1A and FIG. 1B. FIG. 4B illustrates the section IVB-IVB in FIG. 4A. The condenser 3 in this example has a recess 35 and projections 34. More specifically, the condenser 3 has a surface that has the projections 34 and the recess 35. Each of the projections 34 has a surface corresponding to the first region. The recess 35 has a surface corresponding to the second region. The boundary between the first region and the second region may coincide with the boundary between the projections 34 and the recess 35 and may not coincide therewith. A top portion of each of the projections 34 desirably has a surface corresponding to the first region.

The projections 34 and the recess 35 in FIG. 4A and FIG. 4B have a sea-island structure with the projections 34 being islands and the recess 35 being sea. As viewed in a direction perpendicular to the formation surface at which the projections 34 and the recess 35 are formed, each of the projections 34 is surrounded by the recess 35. The shape of each of the projections 34 is circular as viewed in the direction perpendicular to the formation surface. The recess 35 is constituted by a flat surface. The configuration of the projections 34 and the recess 35 is, however, not limited to this example. The number of the projections 34 may be one. The number of the recess 35 may be plural. The condenser 3 may have, for example, the projections 34 and/or the recesses 35. The shape of each of the projections 34 as viewed from the direction perpendicular to the formation surface may be a shape other than a circular shape. As a more specific example, the condenser 3 may have recesses 35 as grooves and the projections 34 as ridges between the grooves adjacent to each other.

When indicated by an area when viewed in the direction perpendicular to the formation surface, the size of each of the projections 34 in the sea-island structure is, for example, 1.8×10⁻² μm² to 12 mm² and may be 1.0 μm² to 0.8 mm². When viewed in the direction perpendicular to the formation surface, the width of each of the projections 34 and the recesses 35 in a groove-ridge structure is, for example, 1 nm to 2.2 mm and may be 5 nm to 1.0 mm. The shape and the size of each of the projections 34 and the recesses 35 can be obtained by, for example, image analysis on an observation image or an enlarged observation image of the formation surface. The enlarged observation image may be, for example, an observation image obtained by a microscope, such as an electron microscope.

The condenser 3 in FIG. 4A and FIG. 4B includes a layer that constitutes the recess 35, and the projections 34 formed on the layer. The recess 35 in FIG. 4A and FIG. 4B is porous. In this case, it is possible to use at least one selected from a water vapor pressure, a capillary aggregation force, and gravity for permeation of moisture in the condenser 3. When the recess 35 has hydrophobicity, for example, it is possible to use permeation of moisture in the form of water vapor. When the recess 35 has hydrophilicity, it is possible to accelerate permeation of condensed moisture.

The configuration of the form A is not limited to the aforementioned example.

Even when the condenser 3 does not have the second region, the condenser 3 can have the same surface shape as the surface shape in the form A presented above as an example. That is, the condenser 3 may have projections and a recess. In this case, each of the projections and the recess can have a surface corresponding to the first region. The condenser 3 may have columnar bodies extending in a direction away from the water absorption surface 71 of the water absorber-drainer 2. In this case, each columnar body can have an outer peripheral surface corresponding to the first region. The entirety of the outer peripheral surface of each columnar body may correspond to the first region. Also in these forms, it is possible, depending on an atmosphere with which the water absorber-drainer 2 and/or the condenser 3 is in contact, to improve efficiency in catching moisture at the condenser 3 and supplying moisture from the condenser 3 to the water absorber-drainer 2.

The first region having hydrophilicity is, for example, a region in which a substance that has a hydrophilic functional group or a composition that contains the substance is disposed. For arrangement of the substance and the composition, for example, coating is usable. Examples of the hydrophilic functional group are a hydroxyl group, a silanol group, a carboxyl group, a sulfonate group, a quaternary ammonium group, a phosphate group, a sulfate group, an amino group, and an amide group. The substance may be polyethylene glycol. The first region may be a region to which hydrophilicity is given by the formation of a specific nanostructure.

The second region having hydrophobicity is, for example, a region in which a substance having a hydrophobic functional group or a composition that contains the substance is disposed. For arrangement of the substance and the composition, for example, coating is usable. The hydrophobic substance is, for example, a hydrocarbon compound having a chain or cyclic alkyl group (at least one hydrogen atom may be replaced with a fluorine atom) and/or an aryl compound having an aromatic ring, such as a benzene ring. The second region may be a region to which hydrophobicity is given by the formation of a specific nanostructure. Examples of the nanostructure that gives hydrophobicity are a lotus-leaf structure and a moth-eye structure. The hydrophobicity of the second region may be a state that is generally referred to as water-repellent properties or super water-repellent properties.

The contact angle of water in the first region is, for example, less than or equal to 90 degrees, may be less than or equal to 60 degrees or less than or equal to 30 degrees. The contact angle of water in the second region is, for example, more than 90 degrees, may be more than or equal to 120 degrees or more than or equal to 150 degrees. In the present specification, the contact angle of water is a value that is evaluated by the sessile drop method defined in the Japanese Industrial Standards (JIS) 83257.

The thickness of the condenser 3 is, for example, 1 nm to 3 mm and may be 5 nm to 1 mm.

The water absorber-drainer 2 absorbs moisture in the first temperature region and drains absorbed moisture in the second temperature region. The second temperature region is on the high temperature side compared with the first temperature region. The state in which the second temperature region is present on the high temperature side compared with the first temperature region means t1H<t2L. Here, t1L represents the lower limit temperature of the first temperature region, t1H (>t1L) represents the upper limit temperature of the first temperature region, t2L represents the lower limit temperature of the second temperature region, and t2H (>t2L) represents the upper limit temperature of the second temperature region. The first temperature region may be in the range of an ordinary temperature, and, for example, the upper limit temperature t1H of the first temperature region may be less than or equal to 50° C., less than or equal to 40° C., or less than or equal to 30° C. The lower limit temperature t1L of the first temperature region is, for example, a freezing temperature of moisture, and a more specific example thereof is more than or equal to 0° C. The ordinary temperature corresponds to a temperature in a living area of a person. The second temperature region may be in the range of a temperature that is controllable by the temperature control member, and the lower limit temperature t2L of the second temperature region is, for example, more than or equal to 30° C., more than or equal to 40° C., more than or equal to 50° C., or more than or equal to 60° C. The first temperature region and the second temperature region are, however, not limited to the aforementioned examples.

The water absorber-drainer 2 has, for example, the following configuration. The configuration of the water absorber-drainer 2 is, however, not limited to the following example as long as the water absorber-drainer 2 absorbs moisture in the first temperature region and drains absorbed moisture in the second temperature region.

An example of the water absorber-drainer 2 includes a polymer (hereinafter “temperature responsive polymer”) having a water absorption property that changes reversibly in response to a temperature. The temperature responsive polymer is, for example, a substance in which hydrophilicity is strong in a low-temperature region, hydrophobicity is strong in a high-temperature region, and changes in the hydrophilicity and the hydrophobicity in response to a temperature are reversible. The polymer can exert a characteristic of absorbing moisture in a low-temperature region and draining absorbed moisture in a high-temperature region. Absorption and drainage of moisture are reversible. A typical example of the temperature responsive polymer is a polymer gel having a water absorption property that changes reversibly in response to a temperature.

In the temperature responsive polymer, a temperature region in which hydrophilicity is strong and a temperature region in which hydrophobicity is strong change in accordance with, for example, a type and a composition of the temperature responsive polymer. A specific temperature responsive polymer used in the water absorber-drainer 2 is selectable in accordance with the first temperature region and the second temperature region that are required for the humidity control device 1A.

As the temperature responsive polymer, polymers of various types such as a polyacrylamide-based, a vinyl acetate copolymer-based, a maleic anhydride copolymer-based, and a polyvinyl alcohol-based, are known. The polymers of these various types are usable as the temperature responsive polymer that can be contained in the water absorber-drainer 2, Example of a polyacrylamide-based temperature responsive polymer are a homopolymer gel and a copolymer gel of N-isopropylacrylamide or a derivative thereof.

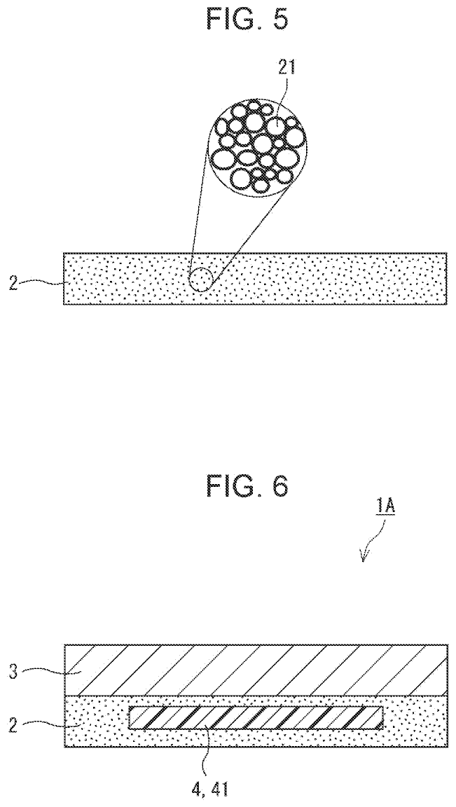

The water absorber-drainer 2 may contain particles constituted by temperature responsive polymers (refer to FIG. 5; the sign 21 in FIG. 5 indicates particles). In this form, it is possible to improve efficiency in absorption and drainage of moisture. The particle diameter of each particle with moisture absorbed therein is, for example, 1 nm to 2.5 μm and may be 10 nm to 1 μm.

The water absorber-drainer 2 may contain a binder for maintaining a shape as a layer. The water absorber-drainer 2 can contain particles constituted by temperature responsive polymers, and a binder that binds particles to each other. The binder is, for example, an uncrosslinked polyvinyl alcohol (PVA), an acrylic resin, an acrylic emulsion, or a water dispersible resin, such as latex. An example of latex is styrene butadiene rubber (SBR).

The thickness of the water absorber-drainer 2 is, for example, 1 nm to 2 mm and may be 0.5 to 1 mm.

The temperature control member 4 changes a temperature of the water absorber-drainer 2 to be in the first temperature region and/or the second temperature region by being operated and/or stopped. In a state in which the temperature control member 4 is not operated, the temperature of the water absorber-drainer 2 may be in the first temperature region, in the second temperature region, or in other temperature regions other than the first temperature region and the second temperature region. An operation pattern of the temperature control member 4 for changing a temperature of the water absorber-drainer 2 from the state to be in the first temperature region and/or the second temperature region can be freely constructed. The operation pattern can include a state in which the temperature control member 4 is not operated. The operation pattern can be changed due to, for example, the temperature and/or the humidity of an atmosphere. The temperature of the water absorber-drainer 2 is typically controlled to be in the second temperature region by the operation of the temperature control member 4. In an example of the temperature control member 4, an operation thereof changes a temperature of the water absorber-drainer 2 in the first temperature region to be in the second temperature region. In this case, the first temperature region may be in the range of an ordinary temperature,

The temperature of the water absorber-drainer 2 may be changed between the first temperature region and the second temperature region alternately by executing an operation pattern with respect to the temperature control member 4. Consequently, absorption and drainage of moisture in the water absorber-drainer 2 can be alternately performed.

Examples of the temperature control member 4 are a heater, a cooler, and a thermoelectric conversion module. The temperature control member 4 is, however, not limited to the aforementioned examples. The thermoelectric conversion module includes one, or two or more thermoelectric conversion elements. The thermoelectric conversion element usually includes a p-type thermoelectric conversion portion, an n-type thermoelectric conversion portion, a first electrode, a second electrode, and a third electrode. The p-type thermoelectric conversion portion is constituted by a p-type thermoelectric conversion material. The n-type thermoelectric conversion portion is constituted by an n-type thermoelectric conversion material. One end of the p-type thermoelectric conversion portion and one end of the n-type thermoelectric conversion portion are electrically connected to each other via the first electrode. The other end of the p-type thermoelectric conversion portion is electrically connected to the second electrode. The other end of the n-type thermoelectric conversion portion is electrically connected to the third electrode. In other words, the first electrode faces the second and third electrodes in the thermoelectric conversion module. The heater and the thermoelectric conversion module are operated by application of a voltage. The cooler may be operated by application of a voltage. In response to the thermoelectric conversion module being operated, the first electrode and one electrode selected from the second and third electrodes facing the first electrode, and one end of each of the n-type and p-type thermoelectric conversion portions electrically connected to the electrodes serve as a heating portion, and the other electrode and the other end of each of the n-type and p-type thermoelectric conversion portions serve as a cooling portion.

An example of Embodiment 1 in which the temperature control member 4 is a thermoelectric conversion module 41 is illustrated in FIG. 6. In the form in FIG. 6, it is possible to, for example, heat the water absorber-drainer 2 and cool the condenser 3 at the same time by applying a voltage to the thermoelectric conversion module 41. Cooling the condenser 3 can contribute to condensation of moisture in the layer.

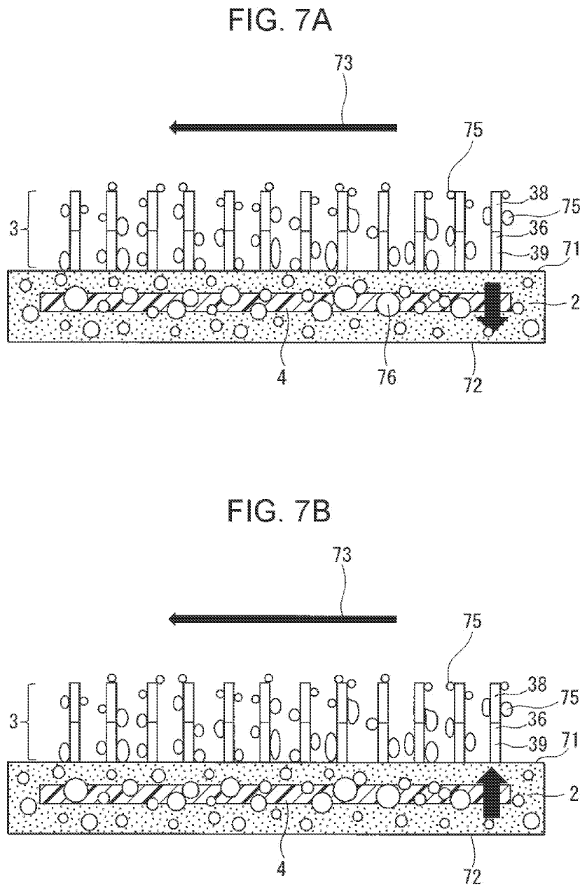

An example of a form of absorption and drainage of water in the humidity control device 1A that includes the temperature control member 4 as the thermoelectric conversion module 41 is illustrated in FIG. 7A and FIG. 7B. In the humidity control device 1A in FIG. 7A and FIG. 7B, the condenser 3 is constituted by the columnar bodies 36. The thermoelectric conversion module 41 is operated such that a temperature decreases toward the upper portion of the thermoelectric conversion module 41, in other words, the water absorption surface 71 and increases toward the lower portion thereof, in other words, the water drainage surface 72 as illustrated in FIG. 7A. Consequently, absorption of moisture from the condenser 3 is accelerated at the water absorption surface 71 of the water absorber-drainer 2 having a low temperature. In addition, the temperature of the condenser 3 decreases, and condensation of moisture in the atmosphere 73 proceeds. Drainage of moisture through the water drainage surface 72 is accelerated at the water drainage surface 72 of the water absorber-drainer 2 having a high temperature. The low temperature is, for example, present in the first temperature region. The high temperature is, for example, present in the second temperature region.

Next, the thermoelectric conversion module 41 is operated such that the upper portion (a part close to the water absorption surface 71) of the thermoelectric conversion module 41 has a high temperature and the lower portion (a part close to the water drainage surface 72) thereof has a low temperature as illustrated in FIG. 7B. Consequently, drainage of moisture through the water drainage surface 72 is suppressed. In the thermoelectric conversion module 41, the speed and the responsiveness of the control of absorption and drainage of water can be improved compared with a heater. Moreover, the thermoelectric conversion module 41 is not easily limited by a temperature of an atmosphere in which the humidity control device 1A is installed. For example, even when the temperature of the atmosphere is between the first temperature region and the second temperature region, the humidity control device 1A can be used.

The temperature control member 4 in Embodiment 1 is provided in the inside of the water absorber-drainer. The temperature control member 4 as the thermoelectric conversion module 41 may be provided at the center of the water absorber-drainer 2 between the water absorption surface 71 and the water drainage surface 72. The location and the form in which the temperature control member 4 is disposed are, however, not limited as long as the temperature control member 4 can change, by being operated, the temperature of the water absorber-drainer 2 to be in the first temperature region and/or the second temperature region.

The temperature control member 4 may have a coating for suppressing entry of moisture into the inside of the member. The coating may cover the entirety of the temperature control member 4. An example of the material that constitutes the coating is a resin.

In the device 1A according to Embodiment 1, the water absorber-drainer 2 and the condenser 3 are in contact with each other. Another layer capable of supplying moisture from the condenser 3 to the water absorber-drainer 2 may be disposed between the water absorber-drainer 2 and the condenser 3. Another layer may be disposed at the second main surface 32 as long as condensation of moisture in an atmosphere at the condenser 3 is possible.

The humidity control device 1A is usable as, for example, a moisture catching device that catches moisture in an atmosphere, a moisture storing device that stores moisture that has been caught, a moisture moving device that moves moisture from the condenser 3 to the water absorber-drainer 2, or a moisture controlling device that includes functions selected from the aforementioned catching, storing, and moving. The humidity control device 1A is usable as, for example, a total heat exchanger in a heat exchange ventilation system. The intended use of the humidity control device 1A is, however, not limited to the aforementioned examples.

### Embodiment 2

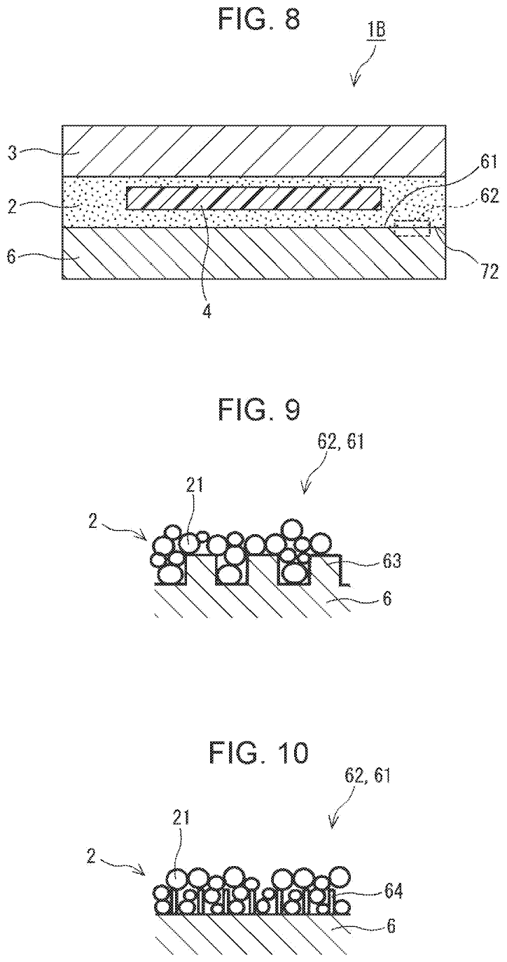

A device according to Embodiment 2 is illustrated in FIG. 8. A device 1B in FIG. 8 has the same configuration as the configuration of the device 1A according to Embodiment 1 except for further including a reinforcer 6 that is in contact with the water drainage surface 72 of the water absorber-drainer 2 and that is capable of allowing moisture drained from the water absorber-drainer 2 to permeate therethrough.

For permeation of moisture, the reinforcer 6 may have, for example, a through hole through which moisture can permeate. The through hole connects two main surfaces of the reinforcer 6 to each other. A direction in which the through hole extends may be the thickness direction of the reinforcer 6. The reinforcer 6 may be a porous layer having a pore that connects the two main surfaces to each other. The reinforcer 6 may be a layer that has a mesh structure. Examples of the material that constitutes the reinforcer 6 are metals, resins, and composite materials thereof. It is possible to use gravity for permeation of moisture in the reinforcer 6 by using the device 1B in a state in which the water absorber-drainer 2 is on or above the reinforcer 6.

When the water absorber-drainer 2 contains particles 21 constituted by temperature responsive polymers, a third region 61 that is, of the two main surfaces of the above-described reinforcer 6, a main surface close to the water absorber-drainer 2 may have projections 63. In this case, the projections 63 may be inserted into the water absorber-drainer 2 such that the particles 21 of the water absorber-drainer 2 are positioned between the mutually adjacent projections 63 (refer to FIG. 9; a portion 62 of a joint portion between the water absorber-drainer 2 and the reinforcer 6 is illustrated in FIG. 9). The particles 21 can each have a volume that greatly differs between a volume when moisture has been absorbed and a volume when moisture has been drained. Therefore, the arrangement of the particles 21 in the water absorber-drainer 2 may be disordered while absorption and drainage of moisture are repeated. Disorder of the arrangement of the particles 21 can degrade the moisture absorbing performance and the moisture draining performance of the water absorber-drainer 2. In the form in FIG. 9, disorder of the arrangement of the particles 21 due to repeated absorption and drainage of moisture can be suppressed by the projections 63.

The projections 63 may be a plate-shaped body 64 extending in a direction away from the reinforcer 6 (refer to FIG. 10). In this form, disorder of the arrangement of the particles 21 can be more reliably suppressed compared with the form illustrated in FIG. 9 since the number of the projections 63 that can be provided on the third region 61 per unit area and the insertion length of each of the projections 63 into the water absorber-drainer 2 can be both increased.

The insertion length of each of the projections 63 into the water absorber-drainer 2 is, for example, 0.5 to 2 mm and may be 0.5 to 1 mm.

The thickness of the reinforcer 6 is, for example, 0.1 to 0.5 mm and may be 0.1 to 0.2 mm.

### Method of Absorbing and Draining Moisture

A method of absorbing and draining moisture can be executed by a device according to the present disclosure. The method includes causing moisture supplied from the condenser 3 to be absorbed by the water absorber-drainer 2 by controlling the temperature of the water absorber-drainer 2 to be in the first temperature region, and causing absorbed moisture to be drained from the water absorber-drainer 2 by controlling the temperature of the water absorber-drainer 2 to be in the second temperature region. The two steps may be alternately executed.

### Method of Generating Power

A method of generating power can be executed by a device according to the present disclosure including a thermoelectric conversion module as the temperature control member 4 and/or a temperature control member 5. The method includes generating power by using a thermoelectric conversion module as a Seebeck-effect module while the thermoelectric conversion module is not operated. The thermoelectric conversion module not being operated may be a module that is incorporated in a device according to the present disclosure for the purpose of power generation. Generated power can be collected by a freely selected method.

### Heat Exchange Ventilation System

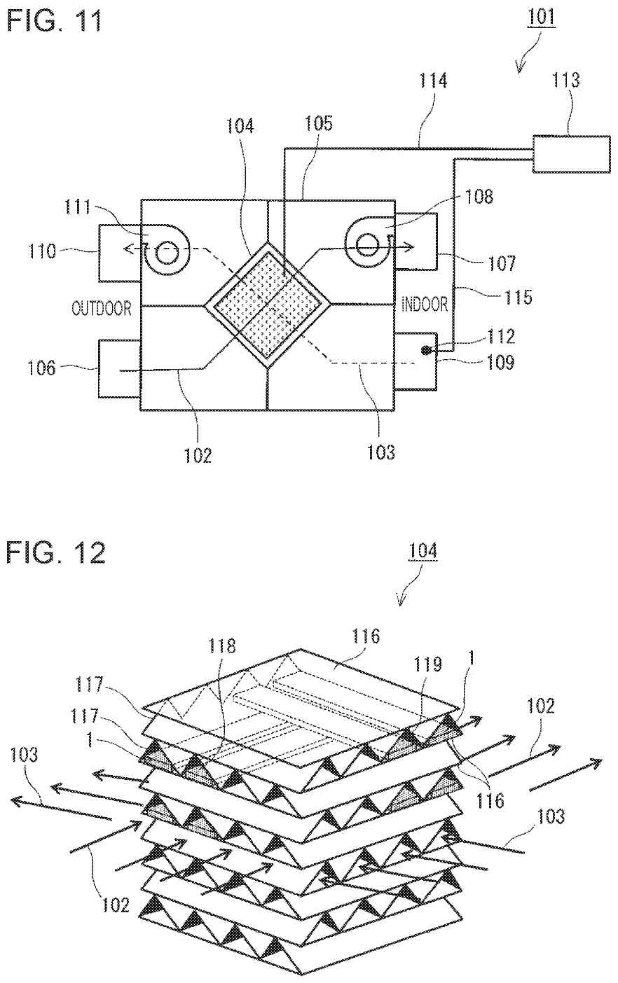

An example of a heat exchange ventilation system according to the present disclosure is illustrated in FIG. 11. A heat exchange ventilation system 101 in FIG. 11 is a system that performs a total heat exchange between first air 102 that is taken in from the outside of a room and second air 103 that is drained from the inside of the room. The system 101 includes a total heat exchanger 104. When the first air 102 and the second air 103 pass through the total heat exchanger 104, temperature and humidity can be exchanged between the first air 102 and the second air 103. The total heat exchanger 104 is accommodated in a heat exchanging apparatus 105 included in the system 101. The heat exchanging apparatus 105 further includes an air intake fan 108 that causes the first air 102 to flow from the outside of a room to the inside of the room, and an exhaust fan 111 that causes the second air 103 to flow from the inside of the room to the outside of the room. The air intake fan 108 forms a flow of the first air 102 from an outside air intake port 106 to an air intake port 107 via the total heat exchanger 104. The exhaust fan 111 forms a flow of the second air 103 from an indoor air intake port 109 to a ventilation portion 110 via the total heat exchanger 104. The system 101 further includes a humidity sensor 112 and a controller 113. The humidity sensor 112 measures the humidity of indoor air. The humidity sensor 112 in FIG. 11 is provided at the indoor air intake port 109. The humidity sensor 112 and the controller 113 are connected to each other by a wire 115. The total heat exchanger 104 and the controller 113 are connected to each other by a wire 114. The heat exchange ventilation system according to the present disclosure includes at least the total heat exchanger 104 and a flow path for each of the first air 102 and the second air 103 that pass through the total heat exchanger 104.

An example of the total heat exchanger 104 is illustrated in FIG. 12. The total heat exchanger 104 in FIG. 12 includes the device 1 according to the present disclosure, partition plates 116 capable of allowing moisture to permeate therethrough, and spacing plates 117. In the total heat exchanger 104, the partition plates 116 and the spacing plates 117 are alternately stacked. The partition plates 116 adjacent to each other in the stacking direction are held in a state of being spaced from each other by the spacing plates 117. The total heat exchanger 104 has, as spaces between the mutually adjacent partition plates 116 held by the spacing plates 117, a first path 118 in which the first air 102 passes and a second path 119 in which the second air 103 passes. The first path 118 and the second path 119 are separated from each other by the partition plates 116 as partition walls, When the first air 102 and the second air 103 pass through the first path 118 and the second path 119, respectively, a total heat exchange can be performed via the partition plates 116 positioned between the two paths. In the total heat exchange, temperature and moisture (in other words, humidity) are exchanged.

In the total heat exchanger 104, the humidity control device 1 is disposed at least one first path 118 and/or at least one second path 119. In this case, a surface of the humidity control device 1 close to the water drainage surface 72 is disposed to be in contact with the partition plates 116. The movement of moisture from the first path 118 to the second path 119 via the partition plates 116 can be controlled by an operation of the humidity control device 1 disposed in the first path 118. The movement of moisture from the second path 119 to the first path 118 via the partition plates 116 can be controlled by an operation of the humidity control device 1 disposed in the second path 119. Being possible to control the movement of moisture means that a total heat exchange between the first air 102 and the second air 103 can be controlled. It is possible, by using the total heat exchanger 104 such that the partition plates 116 with which the humidity control device 1 is in contact is on the lower side in the paths 118 and 119, to use gravity for the movement of moisture.

The total heat exchanger 104 in FIG. 12 has four first paths 118 and four second paths 119. Among these paths, the humidity control device 1 is disposed in each of two first paths 118 and two second paths 119. The proportion of the paths 118 and 119 on each of which the humidity control device 1 is disposed in the paths 118 and 119 of the total heat exchanger 104 is selectable in accordance with performance required for the heat exchange ventilation system 101. When one path 118 and one path 119 are each divided by the spacing plates 117 into sub paths, the humidity control device 1 may be disposed on some of the sub paths in each of the one path 118 and the one path 119 (refer to FIG. 12). Regarding the one path 118 and the one path 119, the proportion of the sub paths on each of which the humidity control device 1 is disposed in all of the sub paths is selectable in accordance with performance required for the heat exchange ventilation system 101.

The controller 113 may control the temperature of the water absorber-drainer 2 of the humidity control device 1 to be in the first temperature region and/or the second temperature region. The temperature of the water absorber-drainer 2 can be controlled by, for example, the temperature control member 4. The controller 113 may control the temperature of the water absorber-drainer 2 to be in the first temperature region and/or the second temperature region in accordance with humidity measured by the humidity sensor 112. The controller 113 may execute other control. The controller 113 can include a calculation device and a storage device for executing control. The storage device may store information for executing control.

In the system 101 in FIG. 11, the humidity sensor 112 measures humidity of indoor air. The system 101 may include a humidity sensor that measures humidity at a freely selected place, instead of the humidity sensor 112 or in addition to the humidity sensor 112. The controller 113 may execute control in accordance with humidity measured by a humidity sensor.

As the partition plates 116, partition plates included in a publicly known total heat exchanger are usable. The partition plates 116 are constituted by, for example, paper. The constitution of the partition plates 116 is, however, not limited as long as the partition plates 116 can separate the first path 118 and the second path 119 from each other and can allow moisture to permeate therethrough.

As the spacing plates 117, spacing plates included in a publicly known total heat exchanger are usable. The spacing plates 117 in FIG. 12 each have a shape that is folded alternately along mountain fold lines and valley fold lines that extend side by side.

In the total heat exchanger 104 in FIG. 12, the first paths 118 and the second paths 119 are provided alternately in a direction (hereinafter “stacking direction”) in which the partition plates 116 and the spacing plates 117 are stacked. The first paths 118 and the second paths 119 may be not provided alternately in the stacking direction. However, a form in which the first paths 118 and the second paths 119 are alternately provided can improve efficiency in the heat exchange in the heat exchange ventilation system 101.

In the total heat exchanger 104 in FIG. 12, the first paths 118 and the second paths 119 are orthogonal to each other when viewed in the stacking direction. The first paths 118 and the second paths 119, however, may be not orthogonal to each other when viewed in the stacking direction.

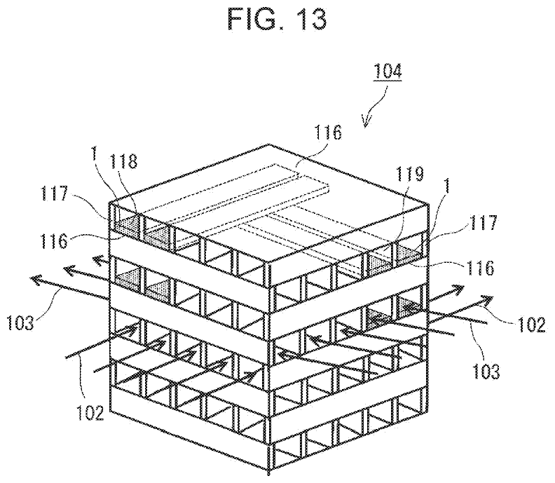

Another example of the total heat exchanger 104 is illustrated in FIG. 13. The total heat exchanger 104 in FIG. 13 has the same configuration as the configuration of the total heat exchanger 104 in FIG. 12 except for a difference in the shape of each of spacing plates 117.

As the air intake fan 108 and the exhaust fan 111, an air intake fan and an exhaust fan included in a publicly known heat exchange ventilation system are respectively usable.

### Method of Controlling Heat Exchange Ventilation System

The heat exchange ventilation system 101 can execute, for example, control by the following control methods.

### Control Method A

The total heat exchanger 104 has at least one first path 118 on which the humidity control device 1 is disposed. The control method A includes measuring humidity of indoor air by the humidity sensor 112, and moving moisture contained in the first air 102 to the second air 103 via the partition plates 116 by causing a controller to execute control A1 or the control A1 and control A2 when measured humidity is more than or equal to a first threshold.

Control A1: The temperature of the water absorber-drainer 2 of the humidity control device 1 disposed in the first path 118 is controlled to be in the second temperature region to cause moisture absorbed by the water absorber-drainer 2 of the humidity control device 1 to be drained from the water absorber-drainer 2.

Control A2: The temperature of the water absorber-drainer 2 of the humidity control device 1 disposed in the first path 118 is controlled to be in the first temperature region to cause moisture supplied from the condenser 3 of the humidity control device 1 to be absorbed by the water absorber-drainer 2.

The control A1 and the control A2 correspond to the above-described method of absorbing and draining moisture by the humidity control device 1. When the water absorber-drainer 2 is in a state in which moisture has been absorbed therein, the control A1 is executed. When the water absorber-drainer 2 is in a state in which moisture has been drained therefrom, the control A2 and the control A1 are executed. When a large amount of moisture is required to be moved, the control A1 and the control A2 may be alternately executed repeatedly. The control A1 and the control A2 can be executed in freely selected patterns in accordance with the state of absorption of moisture in the water absorber-drainer 2, a required amount of movement of moisture, and the like. When the heat exchange ventilation system 101 includes humidity control devices 1, execution patterns of the control A1 and the control A2 can be constructed for each humidity control device 1 in accordance with the state of absorption of moisture in the water absorber-drainer 2 of each humidity control device 1.

### Control Method B

The total heat exchanger 104 has at least one second path 119 in which the humidity control device 1 is disposed. The control method B includes measuring humidity of indoor air by the humidity sensor 112, and moving moisture contained in the second air 103 to the first air 102 via the partition plates 116 by causing a controller to execute the following control B1, or the control B1 and control B2 when measured humidity is less than a second threshold.

Control B1: The temperature of the water absorber-drainer 2 of the humidity control device 1 disposed in the second path 119 is controlled to be in the second temperature region to cause moisture absorbed by the water absorber-drainer 2 of the humidity control device 1 to be drained from the water absorber-drainer 2.

Control B2: The temperature of the water absorber-drainer 2 of the humidity control device 1 disposed in the second path 119 is controlled to be in the first temperature region to cause moisture supplied from the condenser 3 of the humidity control device 1 to be absorbed by the water absorber-drainer 2.

The control B1 and the control B2 correspond to the above-described method of absorbing and draining moisture by the humidity control device 1. When the water absorber-drainer 2 is in a state in which moisture has been absorbed therein, the control B1 is executed. When the water absorber-drainer 2 is in a state in which moisture has been drained therefrom, the control B2 and the control B1 are executed. When a large amount of moisture is required to be moved, the control B1 and the control B2 may be alternately executed repeatedly. The control B1 and the control B2 can be executed in freely selected patterns in accordance with the state of absorption of moisture in the water absorber-drainer 2, a required amount of movement of moisture, and the like. When the heat exchange ventilation system 101 includes humidity control devices 1, execution patterns of the control B1 and the control B2 can be constructed for each humidity control device 1 in accordance with the state of absorption of moisture in the water absorber-drainer 2 of each humidity control device 1.

In the heat exchange ventilation system 101 in which the humidity control device 1 is disposed in both of the first path 118 and the second path 119, both of the control method A and the control method B can be executed. In this case, the second threshold may be less than or equal to the first threshold and may be less than the first threshold.

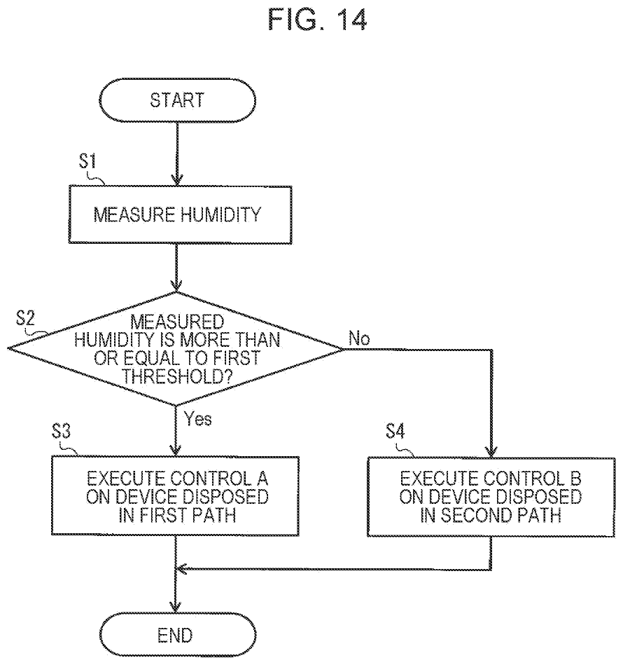

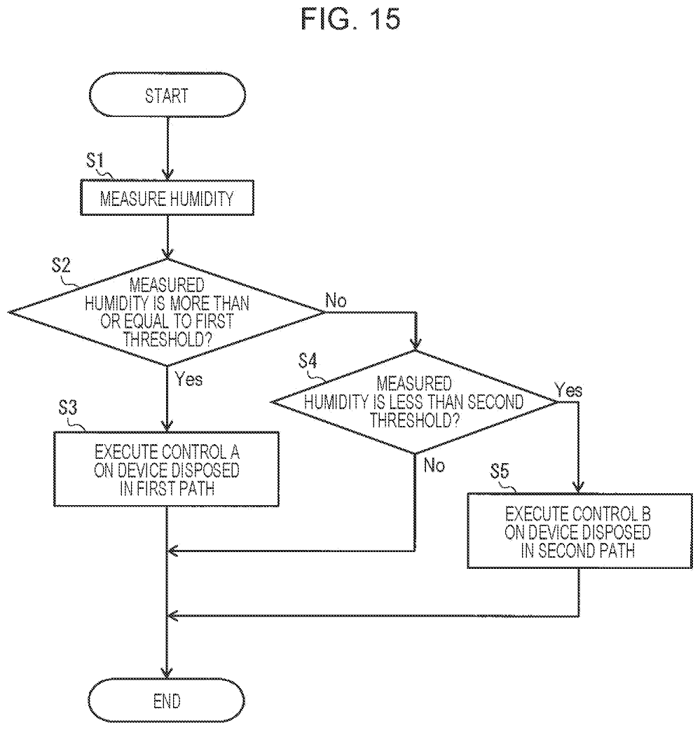

Examples of a flowchart for executing both of the control method A and the control method B in the heat exchange ventilation system 101 are illustrated in FIG. 14 and FIG. 15. In Example 1 in FIG. 14, the first threshold and the second threshold are equal to each other. In Example 2 in FIG. 15, the second threshold is less than the first threshold. Control of the heat exchange ventilation system 101 is, however, not limited to these examples.

### EXAMPLE 1

### FIG. 14

First, the humidity sensor 112 measures humidity of indoor air (S1),

Next, a controller determines whether the measured humidity is more than or equal to the first threshold. The first threshold is, for example, 50% when indicated by relative humidity (S2).

When the humidity is more than or equal to the first threshold (Yes), the control A1 or the control A1 and the control A2 are executed with respect to the humidity control device 1 disposed in the first path 118 (S3). Consequently, moisture contained in the first air 102 is moved to the second air 103, and the first air 102 that has been dried can be sent to the inside of a room. In FIG. 14 and FIG. 15, execution of the control A1, or the control A1 and the control A2 is described as “EXECUTE CONTROL A”.

When the humidity is less than the first threshold (No), the control B1, or the control B1 and the control B2 are executed with respect to the humidity control device 1 disposed in the second path 119 (S4). Consequently, moisture contained in the second air 103 is moved to the first air 102, and the first air 102 that has been humidified can be sent to the inside of the room. In FIG. 14 and FIG. 15. execution of the control B1, or the control B1 and B2 is described as “EXECUTE CONTROL B”.

After S3 or S4, the process is ended,

### EXAMPLE 2

### FIG. 15

First, the humidity sensor 112 measures humidity of indoor air (S1).

Next, a controller determines whether the measured humidity is more than or equal to the first threshold. The first threshold is, for example, 60% when indicated by relative humidity (S2).

When the humidity is more than or equal to the first threshold (Yes), the control A1, or the control A1 and the control A2 are executed with respect to the humidity control device 1 disposed in the first path 118 (S3). Consequently, moisture contained in the first air 102 is moved to the second air 103, and the first air 102 that has been dried can be sent to the inside of a room. In an atmosphere having relative humidity of more than or equal to 60%, mites and mold are easily generated.

When the humidity is less than the first threshold (No), the controller determines whether the measured humidity is less than the second threshold. The second threshold is, for example, 40% when indicated by relative humidity (S4).

When the humidity is less than the second threshold (Yes), the control B1, or the control B1 and the control B2 are executed with respect to the humidity control device 1 disposed in the second path 119 (S5). Consequently, moisture contained in the second air 103 is moved to the first air 102, and the first air 102 that has been humidified can be sent to the inside of the room. In an atmosphere having relative humidity of less than 40%, a person feels dry and is easily affected by diseases such as a cold and influenza.

When the humidity is more than or equal to the second threshold (No), the process is ended. In this case, the humidity of the indoor air is appropriate.

The process is also ended after S3 or S5.

The humidity control device according to the present disclosure is usable in, for example, a heat exchange ventilation system that includes a total heat exchanger.

What is claimed is:

1. A humidity control device comprising:
a condenser; and
a water absorber-drainer, wherein
the condenser has a first region and a second region,
the first region is a region having hydrophilicity and where moisture is condensed,
the condensed moisture is moved by gravity to the water absorber-drainer via the second region,
the water absorber-drainer includes a temperature control member and has a water absorption surface and a water drainage surface,
when a temperature of the water absorber-drainer is in a first temperature region, the water absorber-drainer absorbs through the water absorption surface the moisture moved from the condenser, and
when the temperature of the water absorber-drainer is controlled to be in a second temperature region by an operation of the temperature control member, the water absorber-drainer drains the absorbed moisture through the water drainage surface.

2. The humidity control device according to claim 1,
wherein the condenser and the water absorber-drainer are in contact with each other.

3. The humidity control device according to claim 1,
wherein the second region has hydrophobicity.

4. The humidity control device according to claim 1,
wherein the condenser has a projection and a recess.

5. The humidity control device according to claim 1,
wherein the condenser has a projection and a recess,
the projection having a surface corresponding to the first region,
the recess having a surface corresponding to the second region.

6. The humidity control device according to claim 1,
wherein the condenser has columnar bodies extending in a direction away from the water absorption surface of the water absorber-drainer.

7. The humidity control device according to claim 1,
wherein the condenser has columnar bodies extending in a direction away from the water absorption surface of the water absorber-drainer,
each of the columnar bodies including a first end and a second end, a distance between the first end and the water absorption surface being larger than a distance between the second end and the water absorption surface,
the first end having an outer peripheral surface corresponding to the first region,
the second end having an outer peripheral surface corresponding to the second region.

8. The humidity control device according to claim 1,
wherein the water absorber-drainer includes a polymer having a water absorption property that changes reversibly in response to a temperature.

9. The humidity control device according to claim 8,
wherein the water absorber-drainer includes particles constituted by the polymer.

10. The humidity control device according to claim 1, further comprising:
a reinforcer that is in contact with the water drainage surface of the water absorber-drainer and that is capable of allowing the moisture drained through the water drainage surface to permeate through the reinforcer.

11. The humidity control device according to claim 9, further comprising:
a reinforcer that is in contact with the water drainage surface of the water absorber-drainer and that is capable of allowing the moisture drained through the water drainage surface to permeate through the reinforcer,
the reinforcer having a first surface in contact with the water drainage surface, the first surface having projections,
the projections being inserted into the water absorber-drainer such that the particles of the water absorber-drainer are positioned between the projections adjacent to each other.

12. The humidity control device according to claim 11,
wherein the projections are plate-shaped bodies extending in a direction away from the reinforcer.

13. The humidity control device according to claim 1,
wherein the temperature control member is provided in an inside of the water absorber-drainer.

14. The humidity control device according to claim 1,
wherein the temperature control member is a thermoelectric conversion module.

15. A method of absorbing and draining moisture, comprising:
in the humidity control device according to claim 1,
controlling a temperature of the water absorber-drainer to be in the first temperature region to cause the moisture supplied from the condenser to be absorbed by the water absorber-drainer; and
controlling the temperature of the water absorber-drainer to be in the second temperature region to cause the absorbed moisture to be drained from the water absorber-drainer.

16. A method of generating power, comprising:
in the humidity control device according to claim 14,
generating power by using the thermoelectric conversion module as a Seebeck-effect module while the thermoelectric conversion module is not operated.

17. A heat exchange ventilation system that performs a total heat exchange between first air that is taken in from an outside of a room and second air that is drained from an inside of the room, the heat exchange ventilation system comprising:
a total heat exchanger,
the total heat exchanger including
the humidity control device according to claim 1,
partition plates capable of allowing moisture to permeate through the partition plates, and
spacing plates,
in the total heat exchanger,
the partition plates and the spacing plates being stacked alternately,
the partition plates adjacent to each other in a stacking direction being held in a state of being spaced from each other by the spacing plates,
the total heat exchanger having, as spaces between the partition plates adjacent to each other held by the spacing plates, at least one first path in which the first air passes and at least one second path in which the second air passes,
the at least one first path and the at least one second path being separated from each other with the partition plates as partition walls,
the humidity control device being disposed in the at least one first path and/or the at least one second path such that a surface of the humidity control device dose to the water drainage surface is in contact with the partition plates.

18. The heat exchange ventilation system according to claim 17, further comprising:
a humidity sensor that measures humidity of air in the inside of the room; and
a controller,
the controller controlling a temperature of the water absorber-drainer of the humidity control device to be in the first temperature region and/or the second temperature region in accordance with the humidity measured by the humidity sensor.

19. A method of controlling a heat exchange ventilation system,
the heat exchange ventilation system being the heat exchange ventilation system according to claim 18,
the total heat exchanger having the at least one first path in which the humidity control device is disposed,
the method comprising:
measuring the humidity by the humidity sensor; and
when the measured humidity is more than or equal to a first threshold, causing the controller to execute control A1, or the control A1 and control A2 to move moisture contained in the first air to the second air via the partition plates,
wherein, in the control A1, a temperature of the water absorber-drainer of the humidity control device disposed in the at least one first path is controlled to be in the second temperature region to cause moisture absorbed by the water absorber-drainer to be drained from the water absorber-drainer, and
wherein, in the control A2, a temperature of the water absorber-drainer of the humidity control device disposed in the at least one first path is controlled to be in the first temperature region to cause moisture supplied from the condenser to be absorbed by the water absorber-drainer.

20. A method of controlling a heat exchange ventilation system,
the heat exchange ventilation system being the heat exchange ventilation system according to claim 18,
wherein the total heat exchanger has the at least one second path in which the humidity control device is disposed,
the method comprising:
measuring the humidity by the humidity sensor; and
when the measured humidity is less than a second threshold, causing the controller to execute control B1, or the control B1 and control B2 to move moisture contained in the second air to the first air via the partition plates,
wherein, in the control B1, a temperature of the water absorber-drainer of the humidity control device disposed in the at least one second path is controlled to be in the second temperature region to cause moisture absorbed by the water absorber-drainer to be drained from the water absorber-drainer, and
wherein, in the control B2, a temperature of the water absorber-drainer of the humidity control device disposed in the at least one second path is controlled to be in the first temperature region to cause moisture supplied from the condenser to be absorbed by the water absorber-drainer.

21. The method of controlling the heat exchange ventilation system according to claim 19,
wherein the total heat exchanger has the at least one second path in which the humidity control device is disposed,
the method further comprising:
when the measured humidity is less than a second threshold,
causing the controller to execute control B1, or the control B1 and control B2 to move moisture contained in the second air to the first air via the partition plates,
the second threshold being less than or equal to the first threshold,
wherein, in the control B1, a temperature of the water absorber-drainer of the humidity control device disposed in the at least one second path is controlled to be in the second temperature region to cause moisture absorbed by the water absorber-drainer to be drained from the water absorber-drainer, and
wherein, in the control B2, a temperature of the water absorber-drainer of the humidity control device disposed in the at least one second path is controlled to be in the first temperature region to cause moisture supplied from the condenser to be absorbed by the water absorber-drainer.

22. The method of controlling the heat exchange ventilation system
according to claim 21,
wherein the second threshold is less than the first threshold,

23. The method of controlling the heat exchange ventilation system according to claim 19,
wherein the temperature control member of the humidity control device is a thermoelectric conversion module,
the method further comprising:
while the thermoelectric conversion module is not operated,
collecting power generated in the thermoelectric conversion module by a temperature difference due to a difference between a temperature of the first air and a temperature of the second air.
